(19) United States
(12) Patent Application Publication
(10) Pub. No.: US 2008/0037234 A1
(43) Pub. Date: Feb. 14, 2008

(54) CIRCUIT BOARD AND CIRCUIT STRUCTURE

(76) Inventor: Kuo-Hua Chen, Penghu County (TW)

Correspondence Address: NORTH AMERICA INTELLECTUAL PROPERTY CORPORATION, P.O. BOX 506, MERRIFIELD, VA, 22116, US

(21) Appl. No.: 11/779,888

(22) Filed: Jul. 19, 2007

(30) Foreign Application Priority Data
Aug. 9, 2006 (TW) 095129189

(51) Int. Cl. H05K 7/00

(52) U.S. Cl. 361/777

(57) ABSTRACT

A circuit board which is suitable for carrying a chip and includes a substrate, a wiring layer and a solder mask is provided. The wiring layer is disposed on the substrate. The solder mask is between the substrate and the wiring layer. The solder mask has a chip area, a first opening and a second opening. The chip is suitable for being disposed in the chip area. The first opening and the second opening are respectively located outside two sides of the chip area that are adjacent to each other. The exposed parts of the wiring layer are used for identifying the relative location of the chip relative to the substrate.

### BACKGROUND OF THE INVENTION

1. Field of the Invention

The present invention relates to a circuit board and a circuit structure. In particular, the present invention relates to a circuit board and a circuit structure with positioning marks.

2. Description of the Prior Art

Electronic products play an important role in our life with the improvement of technology. With the increasing demand of the electronic products, producers of the electronic products have increasing demand of the package of the chips in the electronic products. Therefore, to increase the yield of the package of the chips as well as the production yield are urgent problems to be solved.

Taking the wire bonding which is used to electrically connect the chips to the circuit board as an example, producers usually first measure the relative location between the chips and the circuit board before carrying out the wire bonding to accurately use the wires to connect the chips and the circuit board.

FIG. 1 illustrates the positioning of the chips by using the positioning marks on the circuit board of the prior art. In FIG. 1, first a circuit board 100 is provided. The circuit board 100 has a plurality of contacts 110 and a positioning mark 120, which are on a surface 100a of the circuit board 100 and mutually electrically isolative.

Later a chip 200 is provided. The chip 200 has an active surface 200a and a back surface (not shown), which is opposite to the active surface 200a. Additionally, the chip 200 has a plurality of solder pads 210 on the active surface 200a. Then the chip 200 is placed on the circuit board 100, wherein the back surface (not shown) of the chip 200 faces the surface of the circuit board 100.

Then a fiducial pad 210′ among the solder pads 210 is determined. Later, the relative location between the fiducial pad 210′ and the positioning mark 120 is measured. The steps are described here. First the measuring device is aligned with the fiducial pad 210′. Later taking the fiducial pad 210′ as a starting point and moving along the X direction and the Y direction, the distance between the fiducial pad 210′ and the positioning mark 120 along the X direction and the Y direction is determined. By doing so, the conventional method can determine the relative location between the fiducial pad 210′ and the positioning mark 120. In other words, the conventional method can determine the relative location between the chip and the circuit board following the above-mentioned steps.

It is to be noticed that in the conventional method a sufficient space must be left for the positioning mark 120 on the surface 100a designing the circuit board 100. However, it will also decrease the circuit space available to other wires on the surface 100a of the circuit board 100.

In addition, during the measuring of the relative location between the fiducial pad 210′ and the positioning mark 120, the measuring device must first move along the X direction then the Y direction to complete one measurement. It is to be noticed that the conventional method is usually not able to accurately determine the relative location between the fiducial pad 210′ and the positioning mark 120 in a single measurement. In other words, in the conventional method the relative location between the fiducial pad 210′ and the positioning mark 120 can only be determined after several measurements. Accordingly, the production efficiency is therefore jeopardized.

### SUMMARY OF THE INVENTION

Consequently, the present invention provides a circuit board with a positioning mark and a circuit structure with such circuit board. The positioning mark within will not affect the wiring space of other wires on the surface of the circuit board.

The present invention provides a circuit board which is suitable for carrying a chip and includes a substrate, a wiring layer and a solder mask. The wiring layer is disposed on the substrate. The solder mask is between the substrate and the wiring layer. The solder mask has a chip area, a first opening and a second opening. The chip is suitable for being disposed in the chip area. The first opening and the second opening are respectively located outside two sides of the chip area that are adjacent to each other and expose part of the wiring layer. The exposed parts of the wiring layer are used for identifying the relative location of the chip relative to the substrate.

According to one embodiment of the circuit board, the wiring layer includes a plurality of first traces. The first opening exposes at least part of one of the first traces.

According to one embodiment of the circuit board, the wiring layer includes a plurality of second traces. The second opening exposes at least one of parts of the second traces.

According to one embodiment of the circuit board, the first opening is rectangular.

According to one embodiment of the circuit board, the second opening is rectangular.

The present invention provides a circuit structure, which includes a circuit board and a chip. The circuit board includes a substrate, a wiring layer and a solder mask. The wiring layer is disposed on the substrate. The solder mask is between the substrate and the wiring layer. The solder mask has a first opening and a second opening, wherein the first opening and the second opening respectively expose parts of the wiring layer. The chip is disposed on the substrate and the back of the chip faces the substrate. The first opening and the second opening are respectively located outside two sides of the chip that are adjacent to each other. The exposed parts of the wiring layer are used for identifying a relative location of the chip relative to the substrate.

According to one embodiment of the circuit structure, the wiring layer includes a plurality of first traces. The first opening exposes at least part of one of the first traces.

According to one embodiment of the circuit structure, the wiring layer includes a plurality of second traces. The second opening exposes at least one of parts of the second traces.

According to one embodiment of the circuit structure, the first opening is rectangular.

According to one embodiment of the circuit structure, the second opening is rectangular.

According to one embodiment of the circuit structure, one active surface of the chip has a fiducial pad. The chip has a first side and a second side adjacent to each other. The first opening is on the extension of the first side and the second opening is on the extension of the second side.

Because the first opening and the second opening respectively expose part of the wiring layer, the exposed part of the wiring layer may be used as the positioning mark. It is advantageous over the prior art because the positioning mark of the present invention will less likely affect the wiring space of other wires on the surface of the circuit board.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates the positioning of the chips by using the positioning marks on the circuit board of the prior art.

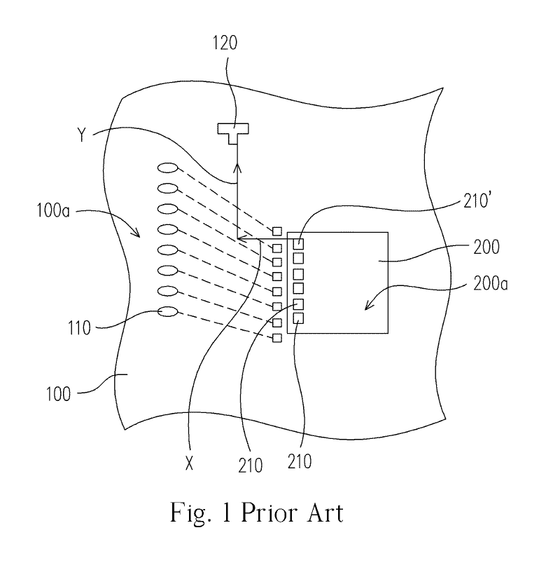

FIG. 2 is a perspective view of the circuit structure of one embodiment of the present invention.

### DETAILED DESCRIPTION

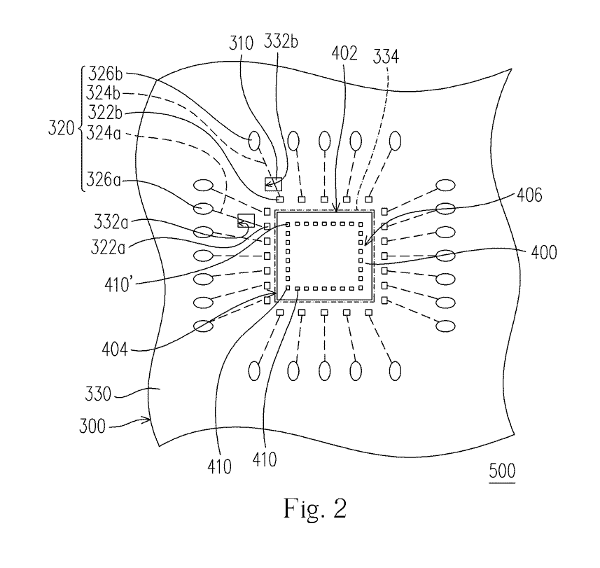

FIG. 2 is a perspective view of the circuit structure of one embodiment of the present invention. The circuit structure 500 includes a circuit board 300 and a chip 400. The circuit board 300 includes a substrate 310, a wiring layer 320 and a solder mask 330. The wiring layer 320 is disposed on the substrate 310. In this embodiment, the wiring layer 320 includes a plurality of first inner contacts 322a, a plurality of second inner contacts 322b, a plurality of first traces 324a, a plurality of second traces 324b, a plurality of first outer contacts 326a and a plurality of second outer contacts 326b. The first trace 324a electrically connects between the first inner contacts 322a and the first outer contacts 326a. The second trace 324b electrically connects between the second inner contacts 322b and the second outer contacts 326b.

The solder mask 330 is disposed on the substrate 310 and the wiring layer 320. The solder mask 330 has a first opening 332a, a second opening 332b and a chip area 334. The first opening 332a and the second opening 332b are respectively located outside two sides of the chip area 334 that are adjacent to each other. In addition, first opening 332a exposes at least part of one of the first trace 324a and the second opening 332b exposes at least part of one of the second trace 324b. In other words, the first opening 332a and the second opening 332b respectively expose parts of the wiring layer 320. Preferably, the first opening 332a may be rectangular and the second opening 332b may be rectangular, too.

The chip 400 is disposed on the substrate 310 and in the chip area 334. When the chip 400 is disposed in the chip area 334, the back of the chip 400 faces the substrate 310 and the profile of the chip 400 overlaps with the profile of the chip area 334. In such a way, the first opening 332a and the second opening 332b are respectively located outside a first side 402 and a second side 404 adjacent to each other of the chip 400.

Based on the circuit structure 500 above, the parts of the wiring layer 320 exposed by the first opening 332a and the second opening 332b, i.e. the exposed first trace 324a and the second trace 324b of the present embodiment may be used as a positioning mark. The positioning marks are used for identifying the relative location of the circuit board 300 relative to the chip 400.

The following introduces the steps of measuring the relative location of the circuit board 300 relative to the chip 400. First, one of a plurality of pads 410 on the active surface of the chip 400 is determined as a fiducial pad 410′. Then, taking the fiducial pad 410′ as the original point, the distance of the fiducial pad 410′ to the wiring layer 320 exposed by the first opening 332a is determined by a measuring device. Later, taking the fiducial pad 410′ as the original point, the distance of the fiducial pad 410′ to the wiring layer 320 exposed by the second opening 332b is determined by a measuring device. In such a way the location of the circuit board 300 relative to the chip 400 is determined in this embodiment. Once the location of the circuit board 300 relative to the chip 400 is determined, the pads 410 may be electrically connected to the first inner contacts 322a and the second inner contacts 322b through the wire bonding process.

More preferably, the relative location of the first opening 332a and the chip 400 and the relative location of the second opening 332b and the chip 400 may be adjusted so as to enhance the efficiency of measuring the relative location of the circuit board 300 relative to the chip 400.

For example, in the embodiment the location of the first opening 332a and the second opening 332b may be adjusted so that the first opening 332a is disposed along the extension of the first side 402 of the chip 400 and the second opening 332b is disposed along the extension of the second side 404 of the chip. In such a way, the fiducial pad 410′ can be taken as the original point to measure the distance of the fiducial pad 410′ to the wiring layer 320 exposed by the first opening 332a along the extension of the first side 402 as well as the distance of the fiducial pad 410′ to the wiring layer 320 exposed by the second opening 332b along the extension of the second side 404.

To sum up, because the first opening and the second opening respectively expose parts of the wiring layer, the present invention uses the exposed parts of the wiring layer as positioning marks. Compared with the prior art, the positioning marks of the present invention less likely affect the layout space of other circuits on the surface of the circuit board.

Additionally, because the first opening may be on the extension of the first side and the second opening may be on the extension of the second side, the present invention may obtain the relative location of the circuit board relative to the chip quicker compared with the prior art.

Those skilled in the art will readily observe that numerous modifications and alterations of the device and method may be made while retaining the teachings of the invention.

What is claimed is:

1. A circuit board for carrying a chip, comprising:
a substrate;
a wiring layer disposed on said substrate; and
a solder mask disposed on said substrate and said wiring layer, said solder mask having a chip area, a first opening and a second opening, said chip being suitable for being disposed in said chip area, said first opening and said second opening being respectively located outside two sides of said chip area that are adjacent to each other and exposing parts of said wiring layer which are used for identifying a relative location of said chip relative to said substrate.

2. The circuit board of claim 1, wherein said wiring layer comprises a plurality of first traces and said first opening exposes at least parts of one of said first traces.

3. The circuit board of claim 1, wherein said wiring layer comprises a plurality of second traces and said second opening exposes at least parts of one of said second traces.

4. The circuit board of claim 1, wherein said first opening is rectangular.

5. The circuit board of claim 1, wherein said second opening is rectangular.

6. A circuit structure, comprising:
a circuit board, comprising:
a substrate;
a wiring layer disposed on said substrate; and
a solder mask disposed on said substrate and said wiring layer, said solder mask having a first opening and a second opening, wherein said first opening and said second opening respectively expose parts of said wiring layer; and
a chip disposed on said substrate and the back of said chip facing said substrate, said first opening and said second opening being respectively located outside two sides of said chip that are adjacent to each other and said exposed parts of said wiring layer being used for identifying a relative location of said chip relative to said substrate.

7. The circuit structure of claim 6, wherein said wiring layer comprises a plurality of first traces and said first opening exposes at least parts of one of said first traces.

8. The circuit structure of claim 6, wherein said wiring layer comprises a plurality of second traces and said second opening exposes at least parts of one of said second traces.

9. The circuit structure of claim 1, wherein said first opening is rectangular.

10. The circuit structure of claim 1, wherein said second opening is rectangular.

11. The circuit structure of claim 6, wherein one active surface of said chip has a fiducial pad, and said chip has a first side and a second side adjacent to each other, and said first opening is disposed along the extension of said first side and said second opening is disposed along the extension of said second side.
